(19) United States
(12) Patent Application Publication
(10) Pub. No.: US 2020/0381400 A1
(43) Pub. Date: Dec. 3, 2020

(54) SEMICONDUCTOR PACKAGE AND SEMICONDUCTOR DEVICE INCLUDING THE SAME

(71) Applicant: SAMSUNG ELECTRONICS CO., LTD., Suwon-si (KR)

(72) Inventors: HEESEOK LEE, Suwon-si (KR); YUNHYEOK IM, Suwon-si (KR); JISOO HWANG, Suwon-si (KR)

(21) Appl. No.: 16/751,468

(22) Filed: Jan. 24, 2020

(30) Foreign Application Priority Data
May 27, 2019 (KR) 10-2019-0062189

(51) Int. Cl. H01L 25/065; H01L 23/522; H01L 23/367; H01L 23/14; H01L 23/31; H01L 23/00

(52) U.S. Cl. CPC H01L 25/0657; H01L 23/5223; H01L 23/3672; H01L 24/73; H01L 23/3157; H01L 24/13; H01L 24/45; H01L 23/145

(57) ABSTRACT

A semiconductor package may include a first substrate, a second substrate at least partially surrounding the first substrate, the first substrate disposed in an opening penetrating the second substrate, and a semiconductor chip on the first substrate. The first substrate may be spaced apart from the second substrate in the opening, and a thickness of the first substrate may be less than a thickness of the second substrate.

### CROSS-REFERENCE TO RELATED APPLICATION

This U.S. non-provisional patent application claims priority under 35 U.S.C. § 119 to Korean Patent Application No. 10-2019-0062189, filed on May 27, 2019, in the Korean Intellectual Property Office, the disclosure of which is hereby incorporated by reference in its entirety.

### TECHNICAL FIELD

The present disclosure relates to semiconductors and, more specifically, to a semiconductor package and a semiconductor device including the same.

### DISCUSSION OF THE RELATED ART

There are many methods by which a semiconductor die may be packaged. According to a ball grid array (BGA) method for semiconductor packaging, a plurality of solder balls may be bonded onto a top surface or bottom surface of a substrate. The solder balls may each be in contact with an external terminal or device.

Semiconductor chips have become highly integrated as the number of circuit elements on a single chip has increased. The larger and more highly integrated a semiconductor chip becomes, the more points of electrical contact will be needed to connect the packaged semiconductor chip to a circuit board or other external devices. As these points of electrical contact may be made with the solder balls, a large number of solder balls may be required in packaged semiconductor chips that are large and highly integrated, such as those semiconductor chips that are used in products such as a server and a modern television.

As the size and complexity of semiconductor chips increases, there is a possibility that a substrate of the semiconductor chip may warp. Thus, a substrate of at least a certain thickness may be used to control warpage. However, when a thick substrate is used, it may be difficult to control power integrity and signal integrity within the semiconductor chip.

When a semiconductor chip is thinly formed to realize a limited package thickness, a thermal resistance within the semiconductor chip may be increased.

### SUMMARY

Embodiments of the inventive concepts may provide a flip chip-ball grid array (FC-BGA) semiconductor package capable of maintaining power integrity and reducing a spreading thermal resistance while maintaining mechanical strength of a general FC-BGA having a large size and a thick substrate. A semiconductor device may include the FC-BGA semiconductor package.

According to an exemplary embodiment of the present disclosure, a semiconductor package includes a first substrate. A second substrate at least partially surrounds the first substrate. The first substrate is disposed in an opening penetrating the second substrate. A semiconductor chip is disposed on the first substrate. The first substrate is spaced apart from the second substrate in the opening. A thickness of the first substrate is less than a thickness of the second substrate.

According to an exemplary embodiment of the present disclosure, a semiconductor device includes a first semiconductor package. A plurality of second semiconductor packages is disposed on the first semiconductor package. The first semiconductor package includes a first substrate, a second substrate including an opening in which the first substrate is disposed, and a semiconductor chip on the first substrate. A thickness of the first substrate is less than a thickness of the second substrate.

According to an exemplary embodiment of the present disclosure, a semiconductor package includes a first substrate. A second substrate at least partially surrounds the first substrate. The first substrate is disposed in an opening penetrating the second substrate. A semiconductor chip is disposed on the first substrate. A plurality of bumps is disposed between the first substrate and the semiconductor chip. A plurality of wires electrically connects the first substrate and the second substrate. A molding member covers the first substrate and the second substrate and fills a gap between the first and second substrates. A plurality of first solder balls is disposed on a bottom surface of the first substrate. A plurality of second solder balls is disposed on a bottom surface of the second substrate. The first substrate is spaced apart from the second substrate in the opening. A thickness of the first substrate is equal to or less than a half of a thickness of the second substrate. A level of a bottom surface of the first substrate is the same as a level of a bottom surface of the second substrate. The first substrate is a coreless substrate, and the second substrate has a core.

### BRIEF DESCRIPTION OF THE DRAWINGS

A more complete appreciation of the present disclosure and many of the attendant aspects thereof will become more apparent in view of the attached drawings and accompanying detailed description, wherein:

FIG. 1A is a plan view illustrating a semiconductor package according to some exemplary embodiments of the inventive concepts;

FIG. 1B is a cross-sectional view taken along a line I-I′ of FIG. 1A;

FIGS. 2A to 2G are cross-sectional views illustrating a method of manufacturing a semiconductor package, according to some exemplary embodiments of the inventive concepts;

FIGS. 3A to 3D are cross-sectional views illustrating examples of a semiconductor package according to some exemplary embodiments of the inventive concepts;

FIG. 4A is a plan view illustrating a semiconductor device including a semiconductor package according to some exemplary embodiments of the inventive concepts;

FIG. 4B is a cross-sectional view taken along a line I-I′ of FIG. 4A;

FIG. 4C is a plan view illustrating an example of a semiconductor device including a semiconductor package according to some exemplary embodiments of the inventive concepts;

FIG. 5A is a plan view illustrating a semiconductor package according to some exemplary embodiments of the inventive concepts;

FIG. 5B is a cross-sectional view taken along a line I-I′ of FIG. 5A;

FIGS. 6A to 6C are cross-sectional views illustrating a method of manufacturing a semiconductor package, according to some exemplary embodiments of the inventive concepts;

FIGS. 7A and 7B are cross-sectional views illustrating examples of a semiconductor package according to some exemplary embodiments of the inventive concepts;

FIG. 8 is a cross-sectional view illustrating an example of an application of a semiconductor package according to some exemplary embodiments of the inventive concepts;

FIG. 9 is a graph showing an effect of reduction of a thermal resistance of a package according to some exemplary embodiments of the inventive concepts; and

FIG. 10 is a graph showing an effect of reduction of an electrical resistance of a package according to some exemplary embodiments of the inventive concepts.

### DETAILED DESCRIPTION OF THE EMBODIMENTS

Semiconductor packages and methods of manufacturing the same, according to exemplary embodiments of the inventive concepts, will be described hereinafter in detail with reference to the accompanying drawings.

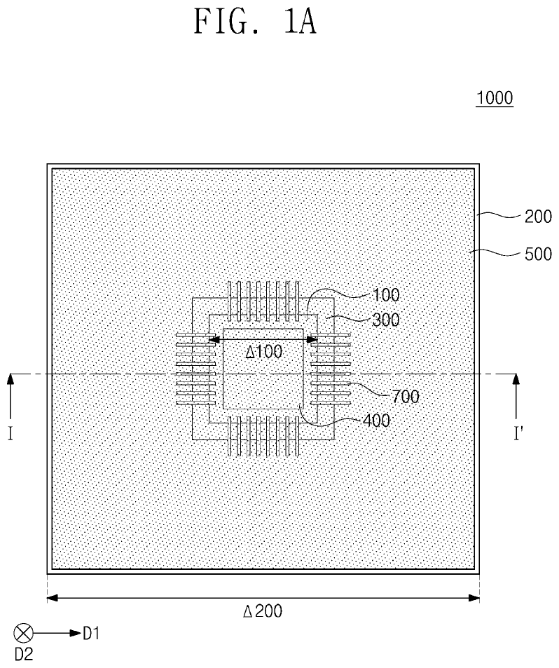

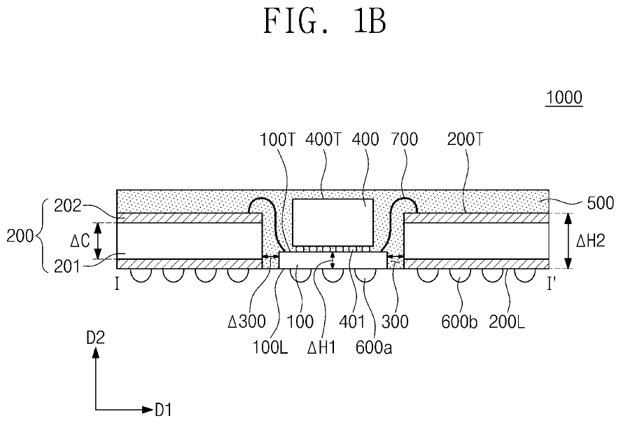

FIG. 1A is a plan view illustrating a semiconductor package according to some exemplary embodiments of the inventive concepts. FIG. 1B is a cross-sectional view taken along a line I-I′ of FIG. 1A. Some components of FIG. 1B are omitted in FIG. 1A for the purpose of ease, clearness and convenience in illustration. However, it is to be understood that these figures are not intended to be exclusive of additional elements, which may be included thereto within the scope of the disclosure.

Referring to FIGS. 1A and 1B, a semiconductor package 1000, according to some exemplary embodiments of the inventive concepts, may include a first substrate 100 and a second substrate 200 at least partially surrounding the first substrate 100. Each of the first and second substrates 100 and 200 may include a printed circuit board (PCB).

A core might not be disposed in the first substrate 100 (i.e., the first substrate 100 may be a coreless substrate), or a relatively thin core may be disposed in a central portion of the first substrate 100. The first substrate 100 may be an organic material-based substrate or a silicon-based substrate. The organic material may include, for example, an epoxy-based compound.

The second substrate 200 may include a core 201 in its central portion. The core 201 may include, for example, a glass fiber. Metal patterns 202 may be provided on opposite surfaces (e.g., top and bottom surfaces) of the core 201.

The first substrate 100 may have a first width 100 in a first direction D1 parallel to a top surface of the first substrate 100. The second substrate 200 may have a second width Δ200 in the first direction D1. The second width Δ200 may be, for example, 40 mm. The first width Δ100 may be less than the second width Δ200. For example, the first width 100 may be ⅓ of the second width Δ200.

The first substrate 100 may have a first thickness ΔH1 in a second direction D2 that is perpendicular to the top surface of the first substrate 100. For example, the first thickness ΔH1 may range from several tens of micrometers (μm) to several hundreds of micrometers (μm). The second substrate 200 may have a second thickness ΔH2 in the second direction D2. The second thickness ΔH2 may range from several hundreds of micrometers (μm) to several millimeters (mm). The first thickness ΔH1 may be less than the second thickness ΔH2. For example, the first thickness ΔH1 may be equal to or less than a half of the second thickness ΔH2.

The core 201 in the second substrate 200 may have a thickness ΔC in the second direction D2, and the thickness ΔC of the core 201 may be, for example, several hundreds of micrometers (μm).

A level of a bottom surface 100L of the first substrate 100 may be the same as a level of a bottom surface 200L of the second substrate 200. Since the first thickness ΔH1 is less than the second thickness ΔH2, a level of a top surface 100T of the first substrate 100 may be lower than a level of a top surface 200T of the second substrate 200.

A gap 300 may exist between the first substrate 100 and the second substrate 200. The gap 300 may be a region between the first substrate 100 and the second substrate 200, and the first substrate 100 and the second substrate 200 may be separated from each other by the gap 300. The gap 300 may have a thickness Δ300 in the first direction D1.

A plurality of first solder balls 600a may be provided on the bottom surface 100L of the first substrate 100. The first solder balls 600a may be in contact with the bottom surface 100L of the first substrate 100. A connection member (e.g., a pad) may be disposed between each of the first solder balls 600a and the first substrate 100. The connection member may be a part of the first substrate 100. A plurality of second solder balls 600b may be provided on the bottom surface 200L of the second substrate 200. The second solder balls 600b may be in contact with the bottom surface 200L of the second substrate 200. A connection member (e.g., a pad) may be disposed between each of the second solder balls 600b and the second substrate 200. The connection member may be a part of the second substrate 200.

A semiconductor chip 400 may be provided on the first substrate 100 so as to overlap the first substrate. The semiconductor chip might not be provided on the second substrate 200 or the gap 300 and might therefore not overlap either the second substrate 200 or the gap 300. The semiconductor chip 400 may include, for example, a system-on-chip (SOC). A level of a top surface 400T of the semiconductor chip 400 may be higher than the level of the top surface 200T of the second substrate 200. Alternatively, the level of the top surface 400T of the semiconductor chip 400 may be the same as or lower than the level of the top surface 200T of the second substrate 200.

A plurality of bumps 401 may be provided between the first substrate 100 and the semiconductor chip 400. The first substrate 100 and the semiconductor chip 400 may be electrically connected to each other through the bumps 401.

A plurality of bonding wires 700 electrically connecting the first and second substrates 100 and 200 to each other may be provided. The semiconductor chip 400 may be electrically connected to the second substrate 200 through the first substrate 100 and the bonding wires 700.

A molding member 500 (e.g. a mold) may cover the first substrate 100, the second substrate 200, and the semiconductor chip 400. The first substrate 100 may be physically and mechanically connected to the second substrate 200 by the molding member 500, which is in contact with both the first and second substrates 100 and 200. The molding member 500 may include, for example, an epoxy resin. The molding member 500 may fill the gap 300. A solder ball might not be disposed under the gap 300 filled with the molding member 500.

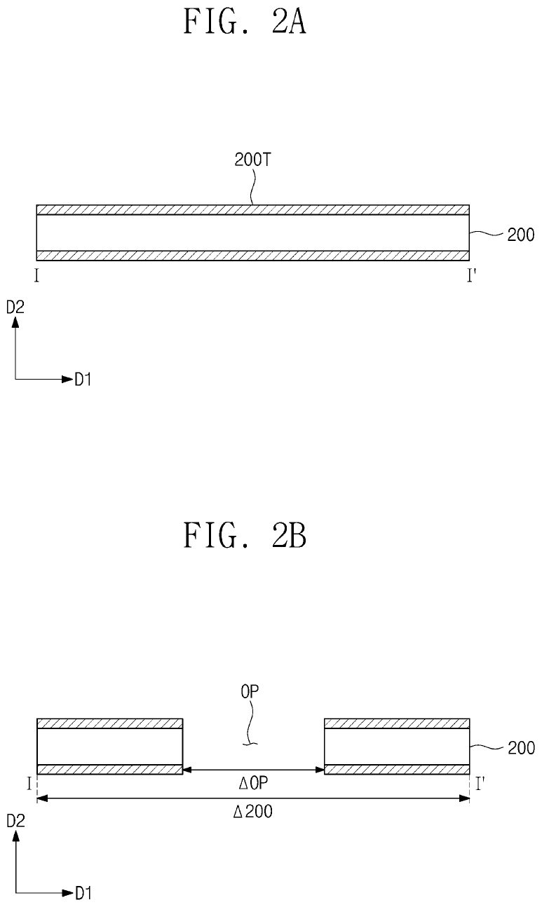

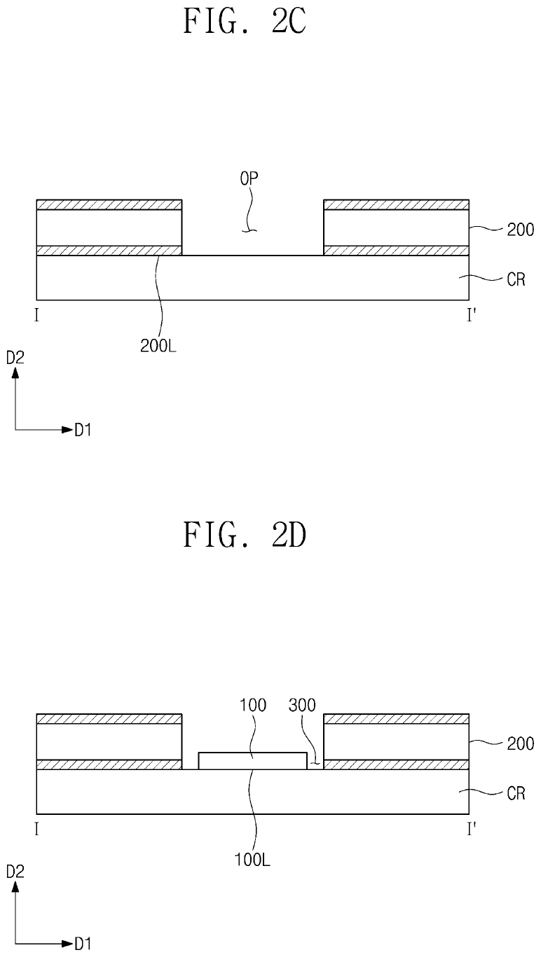

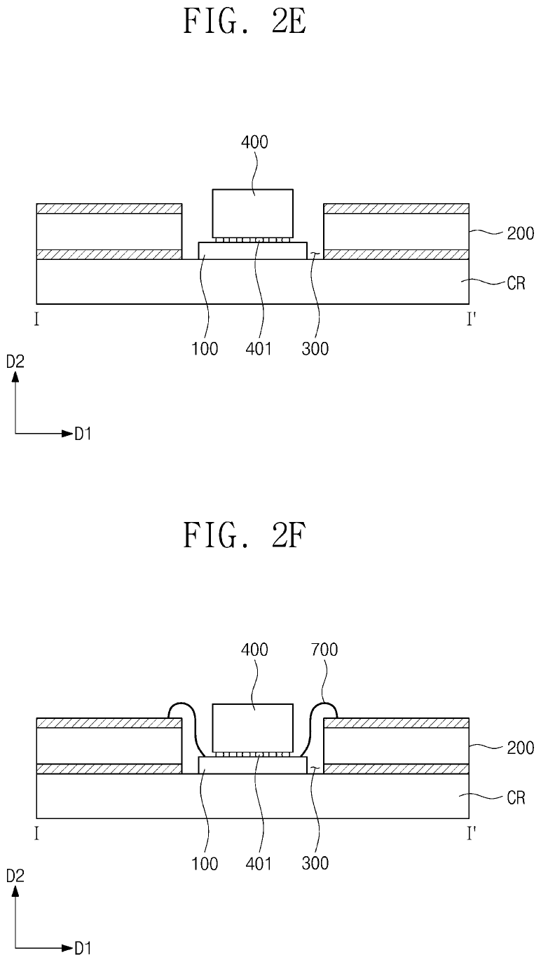

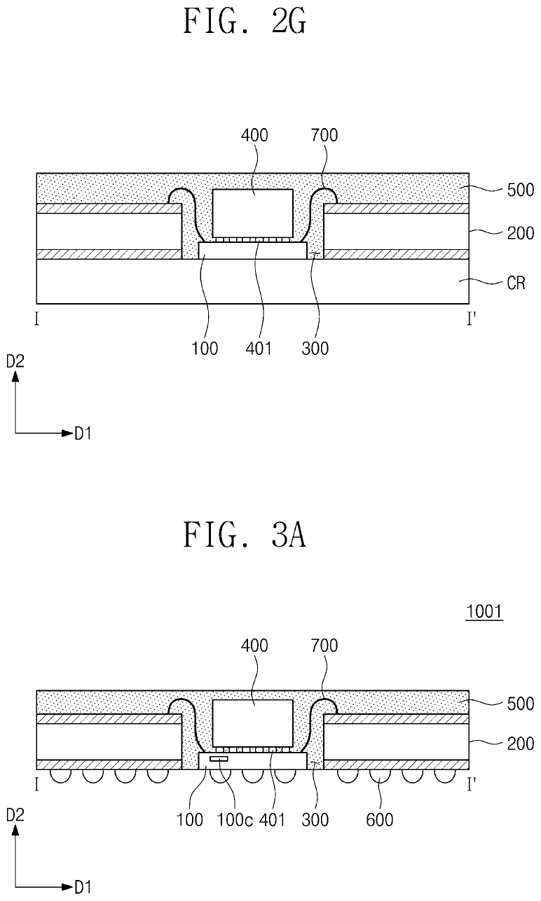

FIGS. 2A to 2G are cross-sectional views illustrating a method of manufacturing a semiconductor package, according to some exemplary embodiments of the inventive concepts. Hereinafter, the descriptions to the same features as mentioned with reference to FIGS. 1A and 1B will be omitted for the purpose of ease and convenience in explanation. It will be assumed that the omitted elements are at least similar to those corresponding elements of FIGS. 1A and 1B.

Referring to FIGS. 2A and 2B, an opening OP may be formed in a portion of the second substrate 200. The portion of the second substrate 200 in which the opening OP is formed may be, for example, a central portion of the second substrate 200. For example, the opening OP may be centered within the second substrate 200. The opening OP may be formed by a mechanical punching or laser drilling process performed in a direction from a region over the second substrate 200 toward the top surface 200T of the second substrate 200. For example, a width ΔOP of the opening OP in the first direction D1 may be ⅓ of the second width Δ200 of the second substrate 200.

Referring to FIG. 2C, a carrier substrate CR may be adhered to the bottom surface 200L of the second substrate 200 in which the opening OP is formed. The carrier substrate CR may be adhered to the bottom surface 200L of the second substrate 200 by an adhesive layer that may be, or may be on, a top surface of the carrier substrate CR.

Referring to FIG. 2D, the first substrate 100 may be disposed in the opening OP of the second substrate 200. The first substrate 100 may be provided on a portion of the carrier substrate CR exposed by the opening OP. The bottom surface 100L of the first substrate 100 may be adhered to the carrier substrate CR by the adhesive layer that may be, or may be on, the top surface of the carrier substrate CR. The gap 300 may extend between the first substrate 100 and the second substrate 200. The gap 300 may be an empty region between the first and second substrates 100 and 200 and may overlap with a portion of the opening OP.

Referring to FIG. 2E, the semiconductor chip 400 may be mounted on the first substrate 100. The semiconductor chip 400 and the first substrate 100 may be connected to each other by a reflow process of bumps 401 between the semiconductor chip 400 and the first substrate 100. This connection may be an electrical connection for transmitting power and/or signals between the semiconductor chip 400 and the first substrate 100.

Referring to FIG. 2F, the bonding wires 700 electrically connecting the first and second substrates 100 and 200 may be formed. The bonding wire 700 may be in contact with a connection member (e.g., a pad) on the first substrate 100 and a connection member (e.g., a pad) on the second substrate 200. This connection may be an electrical connection for transmitting power and/or signals between the first and second substrates 100 and 200.

Referring to FIG. 2G, the molding member 500 may be formed to cover each of the first substrate 100, the second substrate 200, and the semiconductor chip 400. The molding member 500 may fill the gap 300.

Referring again to FIG. 1B, the carrier substrate CR may be removed. A solution treatment and/or a heat treatment may be performed to remove any portion of the adhesive layer remaining on the bottom surface 100L of the first substrate 100, the bottom surface 200L of the second substrate 200, and a bottom surface of the molding member 500 filling the gap 300.

Next, the first solder balls 600a may be formed on connection members (e.g., pads) of the bottom surface 100L of the first substrate 100, and the second solder balls 600b may be formed on connection members (e.g., pads) of the bottom surface 200L of the second substrate 200.

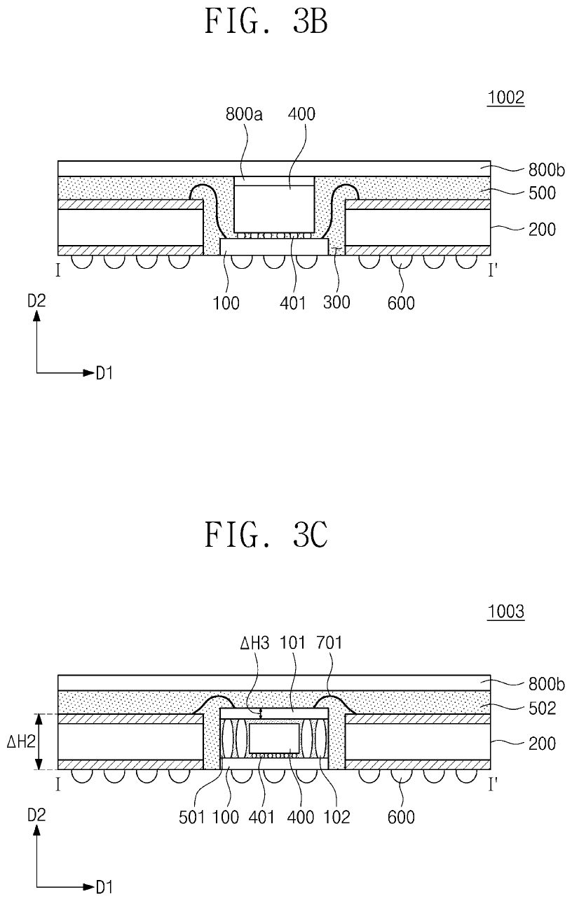

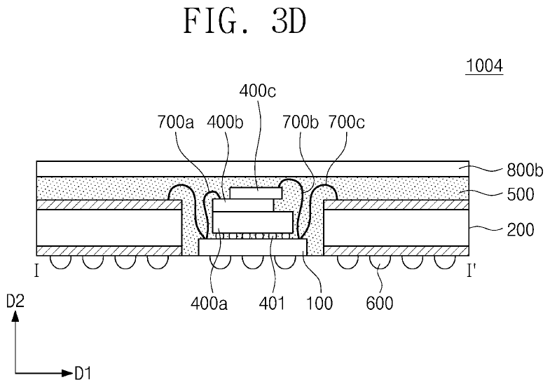

FIGS. 3A to 3D are cross-sectional views illustrating examples of a semiconductor package according to some embodiments of the inventive concepts. Hereinafter, the descriptions to the same features as mentioned with reference to FIGS. 1A and 1B will be omitted for the purpose of ease and convenience in explanation and it is to be understood that omitted features may be at least similar to corresponding features shown in FIGS. 1A and 1B.

Referring to FIG. 3A, a semiconductor package 1001, according to an example of some embodiments of the inventive concepts, may further include a capacitor 100c embedded in the first substrate 100. The embedded capacitor 100c may be electrically connected to the semiconductor chip 400. Solder balls 600 include both the first solder balls 600a that are in contact with the first substrate 100 and the second solder balls 600b that are in contact with the second substrate 200.

Referring to FIG. 3B, a semiconductor package 1002, according to an example of some embodiments of the inventive concepts, may further include a heat conductive material 800a on the semiconductor chip 400, and a heat dissipation plate 800b covering both the heat conductive material 800a and the molding member 500.

For example, the heat conductive material 800a may include thermal grease, a thermal sheet/film, a thermal pad, and/or a thermal adhesive. The heat dissipation plate 800b may include copper (Cu), aluminum (Al), and/or an alloy of one or more of these metals. Heat generated from the semiconductor chip 400 may be effectively released to the outside through the heat conductive material 800a and the heat dissipation plate 800b.

Referring to FIG. 3C, a semiconductor package 1003, according to an example of some embodiments of the inventive concepts, may further include a third substrate 101 on the first substrate 100. The third substrate 101 may be spaced apart from the first substrate 100 and may face the first substrate 100. A third thickness ΔH3 of the third substrate 101 in the second direction D2 may be less than the second thickness ΔH2 of the second substrate 200 in the second direction D2.

The third substrate 101 may be substantially identical to the first substrate 100. For example, the third substrate 101 may also be a coreless organic material-based substrate or an organic material-based substrate having a core having a thickness of several tens micrometers (μm).

A plurality of interconnection members 102 may be disposed between the first substrate 100 and the third substrate 101. The plurality of interconnection members 102 may include a conductive material, and the first substrate 100 and the third substrate 101 may be electrically connected to each other through the interconnection members 102.

A first molding member 501 may be provided to fill a space between the first substrate 100 and the third substrate 101. A second molding member 502 may be provided to cover both the third substrate 101 and the second substrate 200 and to fill a space between the first molding member 501 and the second substrate 200. The second molding member 502 may correspond to the molding member 500 of FIG. 1B. The first and second molding members 501 and 502 may include, for example, an epoxy compound. The first and second molding members 501 and 502 may be made of a same material or may be made of different materials.

A plurality of bonding wires 701 electrically connecting the third substrate 101 and the second substrate 200 may be provided. The semiconductor chip 400 may be electrically connected to the second substrate 200 through the first substrate 100, the interconnection members 102, the third substrate 101, and the bonding wires 701. The heat dissipation plate 800b may be provided on the second molding member 502. Heat generated from the semiconductor chip 400 may be effectively released to the outside through the heat dissipation plate 800b.

Referring to FIG. 3D, a semiconductor package 1004, according to an example of some embodiments of the inventive concepts, may include a plurality of semiconductor chips 400a, 400b, and 400c on the first substrate 100. For example, the plurality of semiconductor chips 400a, 400b, and 400c may include a first semiconductor chip 400a, a second semiconductor chip 400b stacked on the first semiconductor chip 400a, and a third semiconductor chip 400c stacked on the second semiconductor chip 400b. Adhesive layers may be disposed between each of the semiconductor chips 400a, 400b, and 400c.

The first semiconductor chip 400a may be electrically connected to the first substrate 100 through a plurality of bumps 401 being in contact with a bottom surface of the first semiconductor chip 400a.

The second semiconductor chip 400b may be electrically connected to the first substrate 100 through first bonding wires 700a. The third semiconductor chip 400c may be electrically connected to the first substrate 100 through second bonding wires 700b. The first substrate 100 may be electrically connected to the second substrate 200 through third bonding wires 700c. Alternatively, the first through third bonding wires 700a, 700b, and 700c may be omitted and the second semiconductor chip 400b may be electrically connected to the first substrate 100 through the first semiconductor chip 400a while the third semiconductor chip 400c may be electrically connected to the first substrate 100 through the first and second semiconductor chips 400b and 400c. In such an arrangement, there may be additional bumps disposed between the first and second semiconductor chips 400a and 400b, as well as between the third and second semiconductor chips 400c and 400b.

The molding member 500 may cover each of the second substrate 200, the plurality of semiconductor chips 400a, 400b, and 400c, and the first substrate 100. The heat dissipation plate 800b may be provided on the molding member 500. Heat generated from the semiconductor chips 400a, 400b, and 400c, may be effectively released to the outside through the heat dissipation plate 800b.

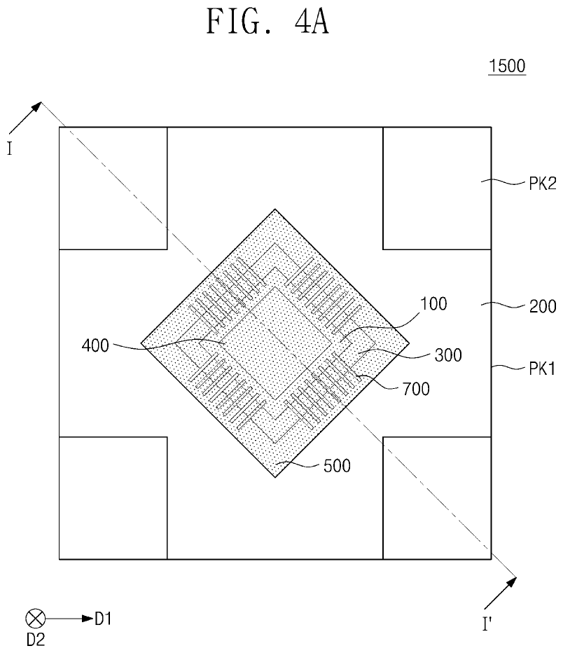

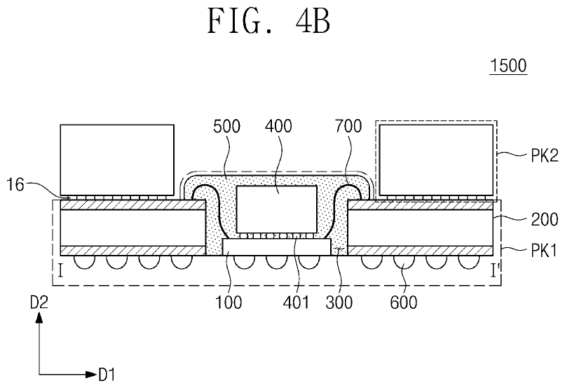

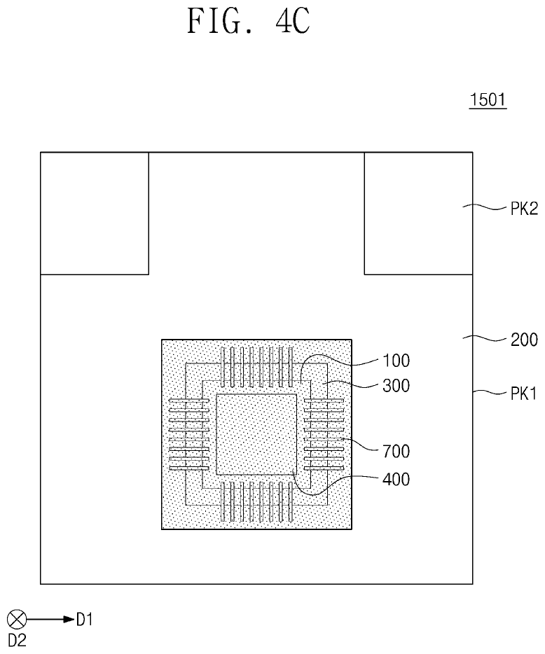

FIG. 4A is a plan view illustrating a semiconductor device including a semiconductor package according to some exemplary embodiments of the inventive concepts. FIG. 4B is a cross-sectional view taken along a line I-I′ of FIG. 4A. Some components of FIG. 4B are omitted in FIG. 4A for the purpose of ease, clearness and convenience in illustration. Hereinafter, the descriptions to the same features as mentioned with reference to FIGS. 1A and 1B will be omitted for the purpose of ease and convenience in explanation. It may therefore be assumed that the omitted elements are at least similar to corresponding elements previously illustrated and described.

Referring to FIGS. 4A and 4B, a semiconductor device 1500, including the semiconductor package, according to some exemplary embodiments of the inventive concepts, may include a first semiconductor package PK1 and a plurality of second semiconductor packages PK2 on the first semiconductor package PK1.

Except for positional relation of the first and second substrates 100 and 200 in a plan view and a region covered by the molding member 500 in a plan view, other components and features of the first semiconductor package PK1 may be substantially identical to as corresponding components and features of the semiconductor package 1000 of FIG. 1B.

Sides of the first substrate 100 of the first semiconductor package PK1 might not be parallel to sides of the second substrate 200 of the first semiconductor package PK1 when viewed in a plan view. For example, each of the sides of the first substrate 100 may form a rotation angle with each of the sides of the second substrate 200. For example, one diagonal line of the first substrate 100 may be parallel to one of two sides of the second substrate 200 and may be perpendicular to the other of the two sides of the second substrate 200.

The molding member 500 may cover both the semiconductor chip 400 and the first substrate 100 and may fill the gap 300. The molding member 500 may cover a portion of the top surface of the second substrate 200.

The second semiconductor packages PK2 may be configured to perform different functions from that of the semiconductor chip 400 disposed on the first substrate 100. The second semiconductor package PK2 may be provided on the top surface of the second substrate 200 and might not be covered by the molding member 500. For example, the semiconductor chip 400 may include a system-on-chip (SOC), and the second semiconductor packages PK2 may include memory semiconductor packages (e.g., DRAM packages).

The second semiconductor packages PK2 may be spaced apart from each other with the semiconductor chip 400 interposed therebetween. The second semiconductor packages PK2 may be disposed on a peripheral portion of the second substrate 200. For example, four second semiconductor packages PK2 may be disposed on the second substrate 200, for example, at four corners thereof.

The second semiconductor packages PK2 may be electrically connected to the first semiconductor package PK1 through a plurality of bumps 16 disposed on the second substrate 200.

FIG. 4C is a plan view illustrating an example of a semiconductor device including a semiconductor package according to some exemplary embodiments of the inventive concepts. Hereinafter, the descriptions to the same features as mentioned with reference to FIGS. 4A and 4B will be omitted for the purpose of ease and convenience in explanation. It may therefore be assumed that the omitted elements are at least similar to corresponding elements previously illustrated and described.

Referring to FIG. 4C, except for positional relation of a first substrate 100, a gap 300 and a second substrate 200 of a first semiconductor package PK1 and the number of second semiconductor packages PK2, other components and features of a semiconductor device 1501 according to the present example may be substantially identical to corresponding components and features of the semiconductor device 1500 described with reference to FIGS. 4A and 4B.

Each side of the first substrate 100 and each side of the second substrate 200 which face each other may be parallel to each other when viewed in a plan view. The first substrate 100 may be disposed in a central portion of the second substrate 200 or may be disposed at a position spaced apart from the central portion of the second substrate 200 in a direction away from the second semiconductor packages PK2. Likewise, the gap 300 may be disposed in the central portion of the second substrate 200 or may be disposed at a position spaced apart from the central portion of the second substrate 200 in the direction away from the second semiconductor packages PK2.

The second semiconductor packages PK2 may be configured to perform different functions from that of the semiconductor chip 400 disposed on the first substrate 100. The second semiconductor package PK2 may be provided on the top surface of the second substrate 200. For example, the second semiconductor packages PK2 may be arranged in a line at a side of the semiconductor chip 400. In FIG. 4C, two second semiconductor packages PK2 are arranged in a line at a side of the semiconductor chip 400. However, embodiments of the inventive concepts are not limited thereto.

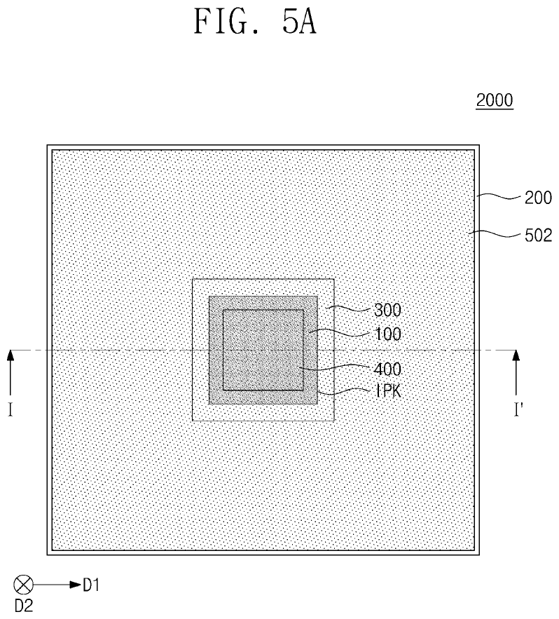

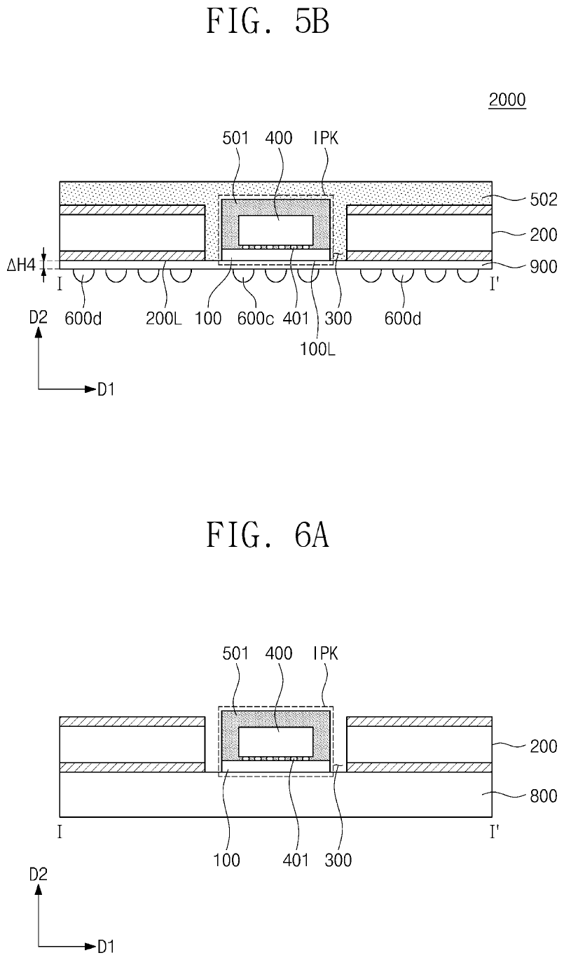

FIG. 5A is a plan view illustrating a semiconductor package according to some exemplary embodiments of the inventive concepts. FIG. 5B is a cross-sectional view taken along a line I-I′ of FIG. 5A. Some components of FIG. 5B are omitted in FIG. 5A for the purpose of ease, clearness and convenience in illustration.

Hereinafter, the descriptions to the same features as mentioned with reference to FIGS. 1A and 1B will be omitted for the purpose of ease and convenience in explanation. It may therefore be assumed that the omitted elements are at least similar to corresponding elements previously illustrated and described.

Referring to FIGS. 5A and 5B, a semiconductor package 2000, according to some embodiments of the inventive concepts, may include an inner package IPK, a redistribution layer 900, a second substrate 200, and a second molding member 502.

The inner package IPK may include a first substrate 100, a semiconductor chip 400, bumps 401, and a first molding member 501. The semiconductor chip 400 may be disposed on the first substrate 100 with the bumps 401 interposed therebetween. The first molding member 501 may at least partially cover the first substrate 100 and the semiconductor chip 400. The first molding member 501 may include, for example, an epoxy material.

The second molding member 502 may at least partially cover the second substrate 200 and the first molding member 501 and may fill the gap 300. The second molding member 502 may include, for example, an epoxy material.

The redistribution layer 900 may be provided on the bottom surface 100L of the first substrate 100 and the bottom surface 200L of the second substrate 200. The redistribution layer 900 may include one or two insulating layers and a metal pattern disposed between the insulating layers. A fourth thickness ΔH4 of the redistribution layer 900 in the second direction D2 may be several tens of micrometers (μm).

A top surface of the redistribution layer 900 may be in contact with the bottom surface 100L of the first substrate 100 and the bottom surface 200L of the second substrate 200. The first substrate 100 and the second substrate 200 may be electrically connected to each other through the redistribution layer 900.

Third solder balls 600c and fourth solder balls 600d may be disposed on a bottom surface of the redistribution layer 900. The third solder balls 600c may at least partially overlap with the first substrate 100 in the second direction D2, and the fourth solder balls 600d may at least partially overlap with the second substrate 200 in the second direction D2. The third solder balls 600c might not overlap with the second substrate 200 and the fourth solder balls 600d might not overlap with the first substrate 100.

The third solder balls 600c and the fourth solder balls 600d may each be in contact with the bottom surface of the redistribution layer 900. A connection member (e.g., a pad) may be disposed between each of the third solder balls 600c and the redistribution layer 900. A connection member (e.g., a pad) may be disposed between each of the fourth solder balls 600d and the redistribution layer 900.

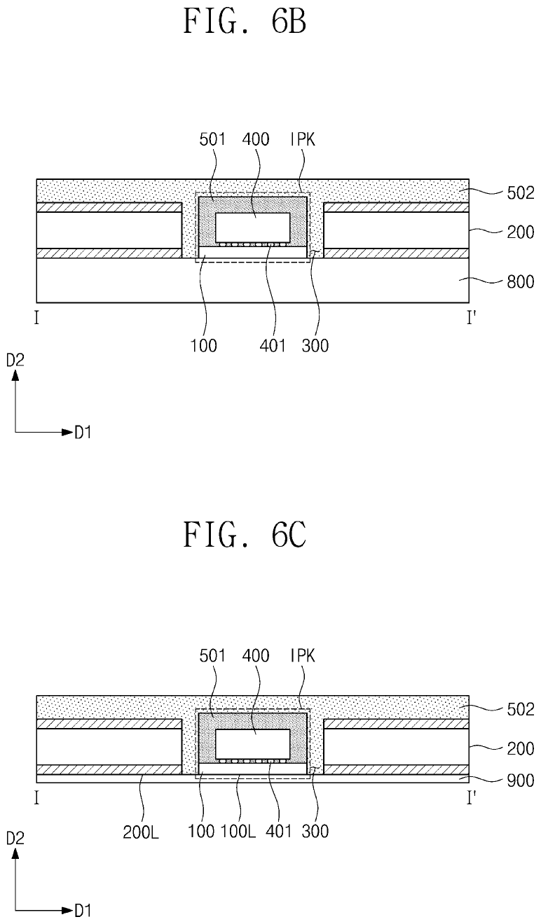

FIGS. 6A to 6C are cross-sectional views illustrating a method of manufacturing a semiconductor package, according to some exemplary embodiments of the inventive concepts.

First, as described with reference to FIG. 2C, a carrier substrate CR may be adhered to the bottom surface 200L of the second substrate 200 in which the opening OP is formed. The carrier substrate CR may be adhered to the bottom surface 200L of the second substrate 200 by an adhesive layer that is part of or on a top surface of the carrier substrate CR.

Referring to FIG. 6A, the inner package IPK may be disposed in the opening OP. The inner package IPK may be provided on a portion of the carrier substrate CR exposed by the opening OP. The bottom surface of the first substrate 100 may be adhered to the carrier substrate CR by an adhesive layer of the top surface of the carrier substrate CR. The gap 300 may be defined between the inner package IPK and the second substrate 200. The gap 300 may be an empty region between the inner package IPK and the second substrate 200 and may at least partially overlap with a portion of the opening OP.

Referring to FIG. 6B, the second molding member 502 may be formed on the carrier substrate CR. The second molding member 502 may cover the second substrate 200 and the inner package IPK. The second molding member 502 may fill the gap 300.

Referring to FIG. 6C, the carrier substrate CR may be removed. A solution treatment and/or a heat treatment may be performed to remove the adhesive layer remaining on the bottom surface 100L of the first substrate 100, a bottom surface of the second molding member 502 in the gap 300, and the bottom surface 200L of the second substrate 200.

Subsequently, the redistribution layer 900 may be formed on the bottom surface 100L of the first substrate 100, the bottom surface of the second molding member 502 in the gap 300, and the bottom surface 200L of the second substrate 200.

Referring again to FIG. 5B, a plurality of solder balls 600c and 600d may be formed on a bottom surface of the redistribution layer 900. The third solder balls 600c and the fourth solder balls 600d may be in contact with the bottom surface of the redistribution layer 900. The third solder balls 600c may at least partially overlap with the first substrate 100 in the second direction D2, and the fourth solder balls 600d may at least partially overlap with the second substrate 200 in the second direction D2. The third solder balls 600c might not overlap with the second substrate in the second direction D2 and the fourth solder balls 600d might not overlap with the first substrate 100 in the second direction D2.

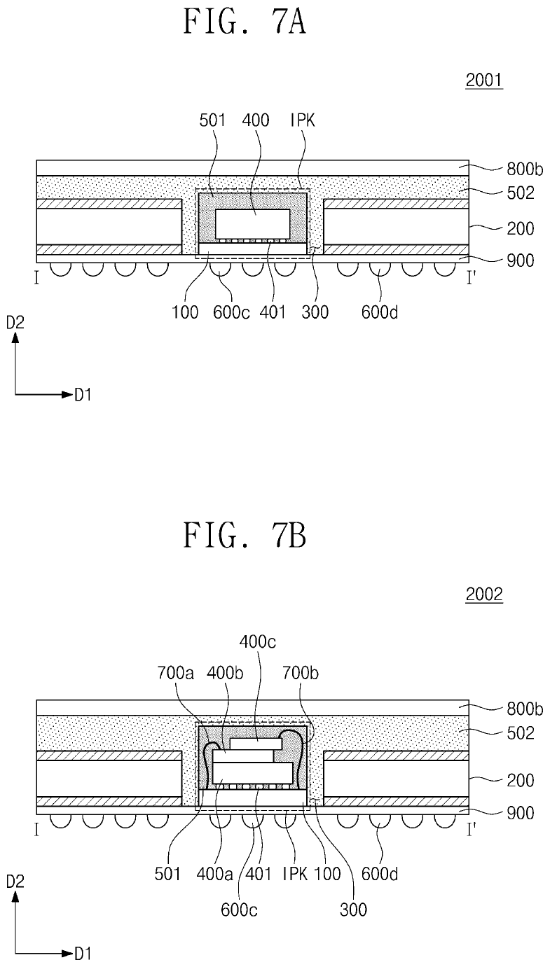

FIGS. 7A and 7B are cross-sectional views illustrating examples of a semiconductor package according to some exemplary embodiments of the inventive concepts. Hereinafter, the descriptions to the same features as mentioned with reference to FIGS. 5A and 5B will be omitted for the purpose of ease and convenience in explanation. It may therefore be assumed that the omitted elements are at least similar to corresponding elements previously illustrated and described.

Referring to FIG. 7A, a semiconductor package 2001, according to the present example, may further include a heat dissipation plate 800b covering the second molding member 502. Heat generated from the semiconductor chip 400 may be effectively released to the outside through the heat dissipation plate 800b.

Referring to FIG. 7B, a semiconductor package 2002, according to the present example, may include an inner package IPK including a plurality of semiconductor chips 400a, 400b, and 400c. For example, the plurality of semiconductor chips 400a, 400b, and 400c may include a first semiconductor chip 400a on the first substrate 100, a second semiconductor chip 400b on the first semiconductor chip 400a, and a third semiconductor chip 400c on the second semiconductor chip 400b. Adhesive layers may be disposed between the semiconductor chips 400a, 400b and 400c.

The first semiconductor chip 400a and the first substrate 100 may be electrically connected to each other through a plurality of bumps 401 disposed therebetween. The second semiconductor chip 400b may be electrically connected to the first substrate 100 through first bonding wires 700a. The third semiconductor chip 400c may be electrically connected to the first substrate 100 through second bonding wires 700b. The first substrate 100 may be electrically connected to the second substrate 200 through the redistribution layer 900.

The first molding member 501 may cover the plurality of semiconductor chips 400a, 400b, and 400c and the first substrate 100. The second molding member 502 may cover the second substrate 200, the inner package IPK, and the gap 300. The heat dissipation plate 800b may be provided on the second molding member 502.

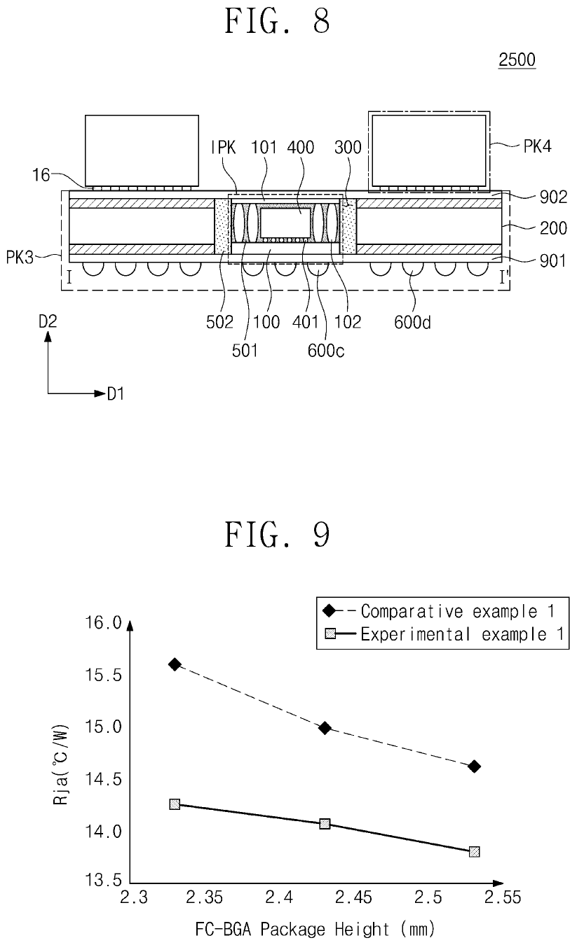

FIG. 8 is a cross-sectional view illustrating a semiconductor device including a semiconductor package, according to some exemplary embodiments of the inventive concepts. Hereinafter, the descriptions to the same features as mentioned with reference to FIGS. SA and SB will be omitted for the purpose of ease and convenience in explanation. It may therefore be assumed that the omitted elements are at least similar to corresponding elements previously illustrated and described.

Referring to FIG. 8, a semiconductor device 2500 including the semiconductor package according to some exemplary embodiments of the inventive concepts may include an inner package IPK, a third semiconductor package PK3 including the inner package IPK, and a plurality of fourth semiconductor packages PK4 on the third semiconductor package PK3.

The inner package IPK may include a first substrate 100 and a third substrate 101 facing the first substrate 100. The third substrate 101 may be spaced apart from the first substrate 100 and may face the first substrate 100. The third substrate 101 may be substantially identical to the first substrate 100. For example, the third substrate 101 may also be a coreless organic material-based substrate or an organic material-based substrate having a core having a thickness of several tens of micrometers (μm).

A plurality of interconnection members 102 may be disposed between the first substrate 100 and the third substrate 101. The plurality of interconnection members 102 may include a conductive material, and the first substrate 100 and the third substrate 101 may be electrically connected to each other through the interconnection members 102.

A first molding member 501 may be provided to fill a space between the first substrate 100 and the third substrate 101.

The third semiconductor package PK3 may include a second substrate 200, a first redistribution layer 901, a second redistribution layer 902, a plurality of solder balls 600c and 600d, and a second molding member 502.

The second substrate 200 may surround the inner package IPK with a gap 300 interposed therebetween. The first redistribution layer 901 may be provided on a bottom surface of the inner package IPK and a bottom surface of the second substrate 200. A top surface of the first redistribution layer 901 may be in contact with a bottom surface of the first substrate 100 and the bottom surface of the second substrate 200. The second redistribution layer 902 may be provided on a top surface of the inner package IPK and a top surface of the second substrate 200. A bottom surface of the second redistribution layer 902 may be in contact with a top surface of the third substrate 101 and the top surface of the second substrate 200.

The plurality of solder balls 600c and 600d may be disposed on a bottom surface of the first redistribution layer 901. Third solder balls 600c may at least partially overlap with the first substrate 100 in the second direction D2. Fourth solder balls 600d may at least partially overlap with the second substrate 200 in the second direction D2. The third solder balls 600c might not overlap with the second substrate 200 in the second direction D2 and the fourth solder balls 600d might not overlap with the first substrate 100 in the second direction D2.

The second molding member 502 may fill the gap 300 between the inner package IPK and the second substrate 200. The inner package IPK and the second substrate 200 may be physically connected to each other by the second molding member 502 being in contact with both the inner package IPK and the second substrate 200.

The fourth semiconductor packages PK4 may be disposed on the second redistribution layer 902. The fourth semiconductor packages PK4 may perform a different function from that of the third semiconductor package PK3.

For example, the third semiconductor package PK3 may be a semiconductor package including a system-on-chip (SOC), and the fourth semiconductor packages PK4 may be semiconductor packages including memory chips (e.g., DRAM chips).

FIG. 9 is a graph showing a reduction effect of a resistance junction ambient (Rja) according to a change in height of a package according to some exemplary embodiments of the inventive concepts.

A sample of an experimental example 1 may be a FC-BGA package including the relatively thin first substrate and the relatively thick second substrate, like the semiconductor package according to the example of the inventive concepts of FIG. 3B. A sample of a comparative example 1 may be a FC-BGA package including a single substrate having the same thickness as the second substrate of the experimental example 1.

A total size of the package of the experimental example 1 may be equal to a total size of the package of the comparative example 1, and a thickness of a semiconductor chip of the experimental example 1 may be greater than a thickness of a semiconductor chip of the comparative example 1. Other components (e.g., a size of a solder ball, a height of a heat dissipation plate, a thickness of a heat conductive material, etc.) of the experimental example 1 may be the same as corresponding components of the comparative example.

Referring to FIG. 9, the resistance junction ambient (Rja) of the experimental example 1 is excellent as compared with that of the comparative example 1. In addition, a change amount of the resistance junction ambient (Rja) value is less even though a height of the package is reduced.

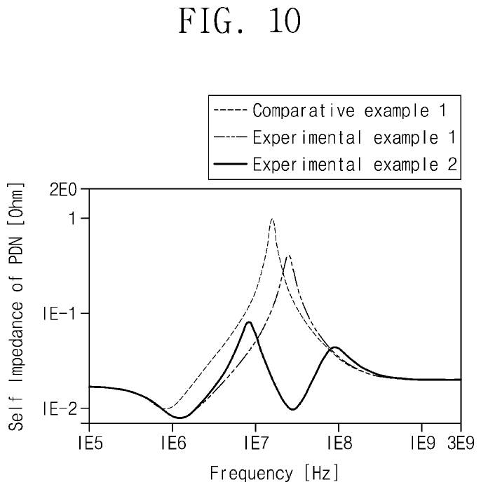

FIG. 10 is a graph showing an effect of reduction of an electrical resistance of a package according to some exemplary embodiments of the inventive concepts.

A sample of an experimental example 1 may be a FC-BGA package including the first relatively thin substrate and the second relatively thick substrate, like the semiconductor package according to the embodiments of the inventive concepts of FIG. 1B.

A sample of an experimental example 2 may be a FC-BGA package including the capacitor embedded in the first substrate, like the example of the inventive concepts of FIG. 3A.

A sample of a comparative example 1 may be a FC-BGA package including a single substrate having the same thickness as the second substrate of the experimental example 1. For example, the package of the comparative example 1 might not use a plurality of substrates.

A self-impedance of PDN of the experimental example 1 according to the inventive concepts is better than that of the comparative example 1, in an experimental frequency range. In addition, referring to the results of the experimental example 2, characteristics of the self-impedance of PDN are more desirable when the package includes the capacitor embedded in the first substrate.

According to exemplary embodiments of the inventive concepts, the first substrate under the semiconductor chip may be the coreless substrate or may include the relatively thin core, and thus the thickness of the first substrate may be less than the thickness of the second substrate. As a result, the thickness of the semiconductor chip may be increased while maintaining a total thickness of the package, and thus thermal characteristics may be more desirable (e.g., reduction of a spreading thermal resistance). In addition, power vias may be distributed at the first substrate under the semiconductor chip. Since the first substrate is relatively thin, lengths of the vias may be reduced to obtain an effect of reduction of an insertion voltage loss and an effect of reduction of cross talk.

The second substrate may be relatively thick and may have excellent strength so as not to easily warp. The first substrate may be physically and mechanically connected to the second substrate by the molding member, and thus mechanical strength of the FC-BGA package with respect to warpage may be maintained or increased.

According to the embodiments of the inventive concepts, it is possible to increase power integrity and thermal characteristics of the semiconductor package while maintaining or increasing mechanical strength of the semiconductor package.

While the inventive concepts have been described with reference to example embodiments, it will be apparent to those skilled in the art that various changes and modifications may be made without departing from the spirits and scopes of the inventive concepts.

What is claimed is:

1. A semiconductor package, comprising:
a first substrate;
a second substrate at least partially surrounding the first substrate, the first substrate disposed in an opening that penetrates the second substrate; and
a semiconductor chip disposed on the first substrate,
wherein the first substrate is spaced apart from the second substrate within the opening, and
wherein a thickness of the first substrate is less than a thickness of the second substrate.

2. The semiconductor package of claim 1, wherein the first substrate is a coreless substrate, and
wherein the second substrate includes a core.

3. The semiconductor package of claim 1, wherein the first substrate includes an organic material.

4. The semiconductor package of claim 3, wherein a bottom surface of the first substrate and a bottom surface of the second substrate are located at a same level.

5. The semiconductor package of claim 1, further comprising:
a molding at least partially covering both the first substrate and the second substrate and at least partially filling a gap between the first substrate and the second substrate;
a plurality of first solder balls in contact with a bottom surface of the first substrate; and
a plurality of second solder balls in contact with a bottom surface of the second substrate,
wherein neither the plurality of first solder balls nor the plurality of second solder balls are disposed under the gap.

6. The semiconductor package of claim 5, further comprising:
a plurality of bonding wires electrically connecting the first substrate and the second substrate.

7. The semiconductor package of claim 5, further comprising:
a capacitor embedded in the first substrate and electrically connected to the semiconductor chip.

8. The semiconductor package of claim 5, further comprising:
a heat conductive material disposed on the semiconductor chip; and
a heat dissipation plate disposed on both the molding and the heat conductive material.

9. The semiconductor package of claim 5, further comprising:
a plurality of conductive bumps disposed between the semiconductor chip and the first substrate,
wherein a level of a top surface of the semiconductor chip is higher than a level of a top surface of the second substrate.

10. The semiconductor package of claim 5, further comprising:
a third substrate facing the first substrate in a direction perpendicular to a top surface of the first substrate with the semiconductor chip interposed therebetween;
an interconnection member disposed between the first substrate and the third substrate and electrically connecting the first substrate and the third substrate; and
a plurality of bonding wires electrically connecting the third substrate and the second substrate.

11. The semiconductor package of claim 5, wherein the semiconductor chip is a first semiconductor chip, the semiconductor package further comprising:
a second semiconductor chip and a third semiconductor chip sequentially stacked on the first semiconductor chip,
wherein the second and third semiconductor chips are each electrically connected to the first substrate through bonding wires.

12. The semiconductor package of claim 1, further comprising:
a redistribution layer disposed on both a bottom surface of the first substrate and a bottom surface of the second substrate; and
first solder balls and second solder balls each disposed on a bottom surface of the redistribution layer,
wherein the first solder balls vertically overlap with the first substrate, and the second solder balls vertically overlap with the second substrate, and
wherein the first substrate and the second substrate are electrically connected to each other through the redistribution layer.

13. The semiconductor package of claim 12, further comprising:
a first molding at least partially covering both the first substrate and the semiconductor chip; and
a second molding at least partially covering both the second substrate and the first molding and filling a gap between the first substrate and the second substrate.

14. A semiconductor device, comprising:
a first semiconductor package; and
a plurality of second semiconductor packages disposed on the first semiconductor package,
wherein the first semiconductor package comprises:
a first substrate;
a second substrate including an opening in which the first substrate is disposed; and
a semiconductor chip disposed on the first substrate,
wherein a thickness of the first substrate is less than a thickness of the second substrate.

15. The semiconductor device of claim 14, wherein the semiconductor chip is a system-on-chip (SOC), and the second semiconductor package is a memory semiconductor package.

16. The semiconductor device of claim 14, further comprising:
a molding;
a plurality of first solder balls disposed on a bottom surface of the first substrate; and
a plurality of second solder balls disposed on a bottom surface of the second substrate,
wherein the molding at least partially covers each of a portion of a top surface of the second substrate, the semiconductor chip, and the first substrate, and
wherein the molding at least partially fills a region between the first and second substrates in the opening.

17. The semiconductor device of claim 16, wherein each of the plurality of second semiconductor packages is disposed on the second substrate and is not covered by the molding, and
wherein each of the plurality of second semiconductor packages are electrically connected to the first semiconductor package through conductive bumps disposed between the second substrate and each of the plurality of second semiconductor packages.

18. The semiconductor device of claim 14, further comprising:
a third substrate facing the first substrate in a direction perpendicular to a top surface of the first substrate with the semiconductor chip interposed therebetween;
an interconnection disposed between the first substrate and the third substrate and electrically connecting the first substrate and the third substrate;
a first redistribution layer disposed on both a bottom surface of the first substrate and a bottom surface of the second substrate; and
a second redistribution layer disposed on both a top surface of the third substrate and a top surface of the second substrate.

19. The semiconductor device of claim 18, further comprising:
a first molding disposed between the first substrate and the third substrate; and
a second molding disposed between the first substrate and the second substrate.

20. A semiconductor package, comprising:
a first substrate;
a second substrate at least partially surrounding the first substrate, the first substrate disposed in an opening penetrating the second substrate;
a semiconductor chip disposed on the first substrate;
a plurality of conductive bumps disposed between the first substrate and the semiconductor chip;
a plurality of wires electrically connecting the first substrate and the second substrate;
a molding at least partially covering both the first substrate and the second substrate and filling a gap between the first and second substrates;
a plurality of first solder balls disposed on a bottom surface of the first substrate; and
a plurality of second solder balls disposed on a bottom surface of the second substrate,
wherein the first substrate is spaced apart from the second substrate in the opening,
wherein a thickness of the first substrate is equal to or less than half of a thickness of the second substrate,
wherein a level of a bottom surface of the first substrate is the same as a level of a bottom surface of the second substrate, and
wherein the first substrate is a coreless substrate, and the second substrate has a core.
